(19) United States
(12) Patent Application Publication
(10) Pub. No.: US 2011/0079271 A1
(43) Pub. Date: Apr. 7, 2011

(54) SPECTRUM-SPLITTING AND WAVELENGTH-SHIFTING PHOTOVOLTAIC ENERGY CONVERTING SYSTEM SUITABLE FOR DIRECT AND DIFFUSE SOLAR IRRADIATION

(76) Inventor: Sergiy DETS, Richmond (CA)

(21) Appl. No.: 12/895,844

(22) Filed: Sep. 30, 2010

Related U.S. Application Data
(60) Provisional application No. 61/247,629, filed on Oct. 1, 2009.

(51) Int. Cl. H01L 31/055

(52) U.S. Cl. 136/247

(57) ABSTRACT

A photovoltaic energy converting system includes: (a) a first photovoltaic converter operable to receive incident solar radiation and convert to electricity those photons of the incident solar radiation having energies less than a predetermined bandgap energy; (b) a fluorescing member positioned for receiving reflected photons having reflected from the first photovoltaic converter, the fluorescing member being operable to produce, in response to the reflected photons, wavelength-shifted photons having energies less than the predetermined bandgap energy; and (c) a second photovoltaic converter operable to convert into electricity the wavelength-shifted photons. The system is thereby advantageously suitable for operation under either direct or diffuse solar irradiation.

### CROSS-REFERENCE TO RELATED APPLICATIONS

This application claims priority of provisional application 61/247,629 filed on Oct. 1, 2009, the entire contents of which are hereby incorporated by reference.

### BACKGROUND OF THE INVENTION

1. Field of Invention

This invention relates to the conversion of solar radiation to electricity and, in particular, to a spectrum-splitting and wavelength-shifting photovoltaic energy converting system suitable for direct and diffuse solar irradiation.

2. Description of Related Art

A photovoltaic device for converting sunlight into electricity is exposed to direct solar radiation predominantly impinging on it from a single point source, namely the sun such as found on a clear and sunny day, and to diffuse solar radiation impinging on it from a multitude of angles at relatively uniform intensity, such as occurs on a cloudy day when direct sunlight is blocked. Some photovoltaic systems attempt to collect solar radiation and to convert the collected solar radiation to electricity. Some photovoltaic systems attempt to concentrate the intensity of solar radiation at a focal point, prior to converting the concentrated solar radiation to electricity.

There have been attempts to collect the generally diffused solar radiation falling on relatively large areas of a photovoltaic device using optical means of simple geometry and of preferably low cost. The dominant low-cost photovoltaic technologies are flat silicon plates and thin film panels that perform under diffuse and direct solar radiation. U.S. Pat. No. 5,248,621 and U.S. Pat. No. 5,503,898, for example, each disclose production methods of texturing, respectively, on crystalline and thin-film photovoltaic cell in order to enhance absorption and light trapping. However, flat silicon plates and film panels convert solar radiation into electricity at typical efficiencies of only 10 to 17 percent.

A solar concentrator optical system is disclosed in U.S. Patent Application Publication No. 2006/0207650 to Winston et al. as concentrating direct solar radiation into a smaller area in accordance with a concentrating power of the system. Winston et al. discloses that the system includes a primary mirror for receiving incident light and reflecting the incident light to a secondary mirror disposed co-planar with the entrance aperture of the primary mirror; the secondary mirror for reflecting light toward a non-imaging concentrator; the concentrator disposed such that the focus of the combination of the primary mirror and the secondary mirror resides at the center of the entrance aperture of the concentrator and which collects light from the secondary mirror; and a solar cell receiving light from the non-imaging solar concentrator to create an electrical output. It is believed that photovoltaic concentrator systems based on the disclosure of Winston et al. are about 30 percent efficient under direct solar irradiation. However, the system of Winston et al. has a narrow field of view such that it suffers from low efficiency under overcast conditions when the incident light is diffuse.

By comparison, the flat silicon plates and film panels are less sensitive than the system of Winston et al. to changes between diffuse and direct irradiation at equal irradiance levels.

A solar concentrator device is described in U.S. Patent 4,425,907 as employing a compound parabolic reflector of relatively large area to focus incident solar radiation onto fluorescent optical fiber; the fluorescent optical fiber, which isotropically emits fluorescent radiation having longer wavelengths than the solar radiation; and an optical wave guide that is coupled to the fluorescent optical fiber and which transmits this fluorescent radiation to a point of use. One disadvantage of such device is that the focusing mirror non-selectively delivers both short-wave and long-wave solar radiation while only radiation within a limited wavelength range that effectively stimulates fluorescence is transmitted through the coupled optical wave guide to the point of use.

It is known from the state of the art that trough-shaped reflective mirrors that reflect radiation towards thermal tubular absorbers are used to generate hot steam with an option to convert the thermal power of the hot steam into electricity. Customarily these devices have not been known to operate in a mode where solar radiation is delivered to both thermal absorbers and photovoltaic converters at once.

In U.S. Pat. No. 4,328,389, issued to Stern et al., the concept of beam splitting was seen in an optical system disclosed as including a metallized parabolic reflector positioned to collect a solar radiation stream of the full spectral content. Stern et al. discloses that the metallized parabolic reflector is positioned to receive a solar light stream illustrated as a direct light stream. The metallized parabolic reflector reflects the solar radiation stream toward a first photovoltaic array of high bandgap photovoltaic cells which absorb and convert to electricity those photons of the reflected solar radiation stream with energies greater than a predetermined cell bandgap energy and which are transparent to lower energy photons with energies less than the predetermined bandgap of the high bandgap photovoltaic cells. A back surface reflector integral with the first photovoltaic array reflects the lower energy photons of the reflected solar radiation stream back through the first photovoltaic array toward a second photovoltaic array comprising low bandgap photovoltaic cells which absorb and convert into electricity those lower energy photons of the twice reflected solar radiation stream. Stern et al. discloses that the first photovoltaic array may comprise aluminum gallium arsenide cells, and that the second photovoltaic array is an array of silicon photovoltaic or gallium arsenide cells. However, it is apparent that the disclosed system was applicable only to concentrate a direct solar light stream (i.e. highly collimated solar radiation) and not intended for the collection and conversion of diffuse radiation, as the metallized parabolic reflector is positioned to only receive a direct solar light stream.

Plastic deformation of silicon-crystal wafers is described in the Japanese Patent 2005-142370 to K. Nakajima and K. Fujiwara and also in the reference K. Nakajima, K. Fujiwara and W. Pan, “Wave-shaped Si crystal wafers obtained by plastic deformation and preparation of their solar cell”, Appl. Phys. Letters, Vol.85, No.24, p.5896-5898, 2004. However, this patent and reference do not disclose using plastic deformation to produce spectrum-splitting and wavelength-shifting photovoltaic energy converting systems.

The potential application of a photovoltaic setup in which shaped silicon would act as a concave mirror, focusing solar radiation onto a conventional solar cell, while generating electricity itself from photons it absorbs is disclosed in the reference K. Nakajima, K. Fujiwara, W. Pan and H. Okuda, “Shaped silicon-crystal wafers obtained by plastic deformation and their application to silicon-crystal lenses”, Nature Materials AOP Published online: 19 Dec. 2004. However, the disclosure of such potential application does not disclose using shaped silicon to produce spectrum-splitting and wavelength-shifting photovoltaic energy converting systems.

U.S. Patent Application Publication No. 2004/0083946 to Wallace, JR. discloses a method and apparatus for concurrent growth of multiple crystalline ribbons from a single crucible. However, Wallace, JR. does not disclose producing spectrum-splitting and wavelength-shifting photovoltaic energy converting systems. Solar panels sold under the trademark String Ribbon™ employing the method of Wallace, JR. are commercially available. However, such commercially available solar panels do not constitute a spectrum-splitting and wavelength-shifting photovoltaic energy converting system.

An object of the invention is to address the above shortcomings.

### SUMMARY

The above shortcomings may be addressed by providing, in accordance with one aspect of the invention, a photovoltaic energy converting system. The system includes: (a) a first photovoltaic converter operable to receive incident solar radiation and convert to electricity those photons of the incident solar radiation having energies less than a predetermined bandgap energy; (b) a fluorescing member positioned for receiving reflected photons having reflected from the first photovoltaic converter, the fluorescing member being operable to produce, in response to the reflected photons, wavelength-shifted photons having energies less than the predetermined bandgap energy; and (c) a second photovoltaic converter operable to convert into electricity the wavelength-shifted photons.

The first photovoltaic converter may have a front surface and a back surface opposite the front surface. The incident solar radiation may be received by the first photovoltaic converter through the front surface. The reflected photons may be predominantly reflected at the front surface. The reflected photons may predominantly have energies greater than the predetermined bandgap energy. The first photovoltaic converter may be dimensioned to define a focal point. The first photovoltaic converter may be dimensioned to concentrate the reflected photons toward the focal point. The first photovoltaic converter may have a front surface and a back surface opposite the front surface. The incident solar radiation may be received by the first photovoltaic converter through the front surface. The first photovoltaic converter at the front surface may be substantially parabolically concave. The second photovoltaic converter may have a receiving surface through which the wavelength-shifted photons are received. The second photovoltaic converter at the receiving surface may be substantially hemispherically concave. The first photovoltaic converter at the front surface may be substantially arcuately concave. The system may include an additional unit of the first photovoltaic converter disposed adjacently apart from the first photovoltaic converter. The second photovoltaic converter may be attached to the additional photovoltaic converter at a back side thereof. The fluorescing member may be disposed substantially between the first photovoltaic converter and the second photovoltaic converter. The fluorescing member may be dimensioned to have a terminal end. The fluorescing member may be operable to guide the wavelength-shifted photons toward the terminal end. The second photovoltaic converter may be optically coupled to the fluorescing member at the terminal end. The first photovoltaic converter may have a front surface. The incident solar radiation may be received by the first photovoltaic converter through the front surface. The second photovoltaic converter may be attached to the first photovoltaic converter at the front surface. The second photovoltaic converter may be in thermal contact with the first photovoltaic converter. The first photovoltaic converter may include the second photovoltaic converter. The fluorescing member may be dimensioned to have a terminal end and one or more sides separate from the terminal end. The fluorescing member may be operable to guide a first subset of the wavelength-shifted photons toward the terminal end. The fluorescing member may be operable to emit a second subset of the wavelength-shifted photons from the fluorescing member at the sides. The system may include a third photovoltaic converter positioned for receiving the second subset. The third photovoltaic converter may include a pair of substantially planar photovoltaic devices disposed at an angle to each other. The third photovoltaic converter may be dimensioned to have a semi-cylindrical receiving surface through which the second subset is received. The system may include a reflector operable to reflect the reflected photons toward the first photovoltaic converter. The fluorescing member may be disposed between the reflector and the first photovoltaic converter. The second photovoltaic converter may be disposed between the fluorescing member and the first photovoltaic converter. The first photovoltaic converter may include the second photovoltaic converter.

In accordance with another aspect of the invention, there is provided an energy converting system. The system includes: (a) first means for receiving incident solar radiation, converting to electricity those photons of the incident solar radiation having energies less than a predetermined bandgap energy, and reflecting reflected photons having energies greater than the predetermined bandgap; (b) second means for producing, in response to the reflected photons, wavelength-shifted photons having energies less than the predetermined bandgap energy; and (c) third means for converting into electricity the wavelength-shifted photons.

In accordance with another aspect of the invention, there is provided an improved inherent spectrum-splitting photovoltaic concentrator system equipped with a curved reflector that receives broadband solar radiation and absorbs and converts into electricity those photons with lower bandgap energies of solar spectrum and reflects and concentrates higher bandgap energy solar radiation in a radiation path toward a predetermined spatially confined area of use. A first photovoltaic means, which is preferably shaped into spectrally selective reflector from plastically deformed silicon wafer, absorbs and converts into electricity photons falling below the first predetermined bandgap of energy defining longwave visible radiation, so that it is predominantly photons with higher bandgap energy that comprise the stream that is reflected and concentrated by the first photovoltaic means towards the second photovoltaic means or thermal absorber. In the preferred embodiment, the first photovoltaic means converts into electricity many of those photons with energies less than a predetermined energy level and reflects higher energy photons. Reflected high energy photons are concentrated by this first photovoltaic means into a radiation stream that is partially transmitted, absorbed and converted by the fluorescent material into a radiation stream that carries lower bandgap energy photons toward the second photovoltaic means. In its simplest sense, an apparatus for the spectral splitting and collection of broadband solar radiation comprises a curved photovoltaic receiver, concentrating at least part of incoming radiation stream towards the fluorescent waveguiding material which is optically coupled to a second photovoltaic element. Thus, the present invention discloses a novel means of splitting the incoming combination of diffuse and direct solar radiation into energy bands and directing the energy toward corresponding photovoltaic cells with improved photovoltaic conversion. Accordingly, an improved solar concentrator provides user-friendly, yet economical means of increasing the efficiency of photovoltaic conversion under direct and diffuse solar radiation.

In accordance with another aspect of the invention, there is provided an inherent spectrum-splitting photovoltaic concentrator of solar radiation, comprising: (a) a primary photovoltaic means for reflecting and concentrating radiation impinging over relatively wide area so as to impinge on the surface of a fluorescent waveguide; (b) primary photovoltaic means adapted to absorb the incoming solar radiation and convert those photons with energies lesser than the first predetermined bandgap energy, said means being predominantly absorptive in longwave spectral range; (c) primary photovoltaic means adapted to reflect those photons with energies greater than the first predetermined bandgap energy, said being highly reflective in shortwave spectral range of solar radiation; the fluorescent waveguide formed from a transparent material placed near the focal point of the primary photovoltaic means, said fluorescent waveguide material is characterized by the excitation curve approximately overlapping spectral range of the reflectance curve of the primary means and have emission wavelength curve shifted towards longer wavelengths; (d) a curved secondary photovoltaic means positioned near said fluorescent waveguide and shaped so as to maximize the absorbtion of radiation both passed from the primary photovoltaic means and emitted from said fluorescent waveguide; and (e) secondary photovoltaic means adapted to absorb and convert into electricity those photons with energies greater than the first predetermined bandgap energy.

Other aspects and features of the present invention will become apparent to those of ordinary skill in the art upon review of the following description of embodiments of the invention in conjunction with the accompanying figures and claims.

### BRIEF DESCRIPTION OF THE DRAWINGS

In drawings which illustrate by way of example only embodiments of the invention:

FIG. 1 is a diagram of a photovoltaic energy converting system in accordance with one embodiment of the present invention.

FIG. 2 is a representative reflectance graph of a first photovoltaic receiver with and without antireflective coating.

FIG. 3 is a representative graph of the excitation and emission spectra for the fluorescent material utilized in accordance with the invention.

FIG. 4 is a perspective view of one of the embodiments of the present invention, showing a parabolically concave primary photovoltaic receiver and a hemispherical secondary photovoltaic receiver.

FIG. 5 is a perspective view of yet another embodiment of the present invention, showing a longitudinal fluorescent material target waveguide, a planar secondary photovoltaic receiver adjacent a side of the longitudinal fluorescent material target waveguide, and a pair of tertiary photovoltaic receivers adjacent opposing ends of the longitudinal fluorescent material target waveguide.

FIG. 6 is a perspective view of yet another embodiment of the present invention, showing a pair of planar secondary photovoltaic receivers disposed at an angle to each other.

FIG. 7 is a perspective view of yet another embodiment of the present invention, showing a semi-cylindrical secondary photovoltaic receiver adjacent a side of a cylindrical fluorescent material target waveguide.

FIG. 8 is a perspective view of yet another embodiment of the present invention, showing a fluorescent material target waveguide having ends terminating at a front surface of a primary photovoltaic receiver.

FIG. 9 is a perspective view of yet another embodiment of the present invention, showing a secondary photovoltaic receiver attached to the back surface of a primary photovoltaic receiver and a fluorescent material target attached to the secondary photovoltaic receiver.

FIG. 10 is a diagram of another embodiment of the present invention, showing a secondary reflector operable to render the system more compact by folding the light path extending between a primary photovoltaic receiver and a secondary photovoltaic receiver.

### DETAILED DESCRIPTION

An energy converting system includes: (a) first means for receiving incident solar radiation, converting to electricity those photons of said incident solar radiation having energies less than a predetermined bandgap energy, and reflecting reflected photons having energies greater than said predetermined bandgap; (b) second means for producing, in response to said reflected photons, wavelength-shifted photons having energies less than said predetermined bandgap energy; and (c) third means for converting into electricity said wavelength-shifted photons.

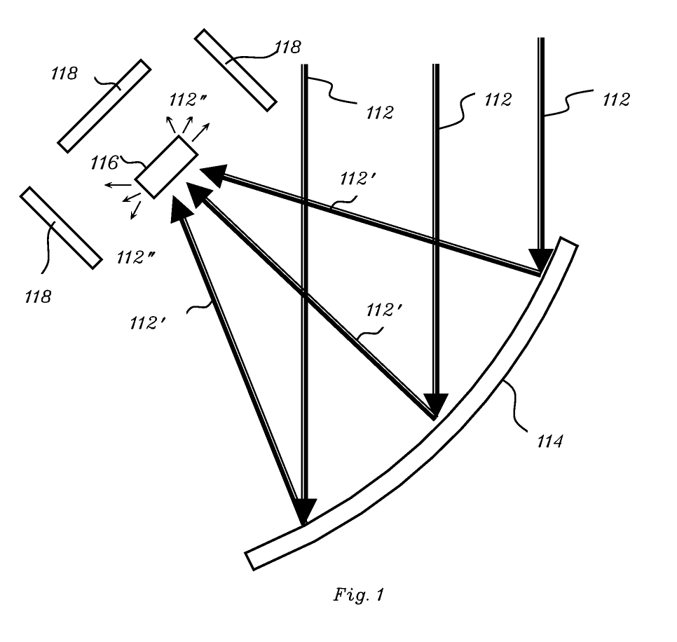

Referring to FIG. 1, the system according to a first embodiment of the invention is illustrated. The system illustrated in FIG. 1 relates to solar collectors, specifically to solar electromagnetic radiation concentrators that allow users to convert diffuse and direct solar radiation into more useful forms of energy by employment of both spectral splitting and redirecting of incoming solar radiation towards points of more efficient utilization.

Referring to the diagram on FIG. 1, an inherent spectrum splitting of the incoming solar radiation stream is carried out in accordance with the first embodiment. The radiation stream 112 impinges upon a first photovoltaic receiver 114 and is spectrally transformed into a radiation stream 112′ being redirected towards the secondary photovoltaic receiver 118. The primary photovoltaic receiver 114 comprises an array of intrinsic high bandgap photovoltaic cells which absorb and convert into electricity those photons of the incoming radiation stream 112 which have energies lower than the predetermined cell bandgap and predominantly reflects radiation stream 112′ composed of greater energy photons. Furthermore, the reflected radiation stream 112′ interacts with the fluorescent material target 116 where it undergoes scattering while also excites to produce fluorescent stream 112″ as a result of high energy photons interaction. Scattered fluorescent radiation stream 112″ that emanates from the bulk of the fluorescing material 116 and carries lower energy photons is absorbed and converted into electricity by secondary photovoltaic receivers 118, which have high photovoltaic conversion efficiency for the 112″ stream. The first photovoltaic receiver 114 preferably constitutes a parabolic trough mirror and may be constructed utilizing plastic deformation of silicon-crystal wafer or by pulling silicon wafers out of a molten solution, for example.

For ease of illustration in FIG. 1, the usual electrical connections and utilization devices of associated electrical circuitry for the photovoltaic receivers are omitted but are well within the scope of the skilled artisan to provide. Such utilization devices of associated electrical circuitry typically includes cell connecting fingers, electrical bus bars, diodes and other electrical components, and any combination thereof for example.

In general, the fluorescent material target 116 may be any device, component, material, fluorescing member or sub-system operable to produce the radiation stream 112″ in response to the radiation stream 112′ such that the photons of the radiation stream 112″ have average energies and wavelengths different from the average energies and wavelengths of the photons of the radiation stream 112′. Preferably, the photons of the radiation stream 112″ have on average lower energies and longer wavelengths than the photons of the radiation stream 112′. Such device, material, fluorescing member or sub-system may produce the radiation stream 112″ in response to the radiation stream 112′ by any suitable means, method or technique, including by the use of fluorescing elements or compounds such as fluorescing dyes, by the use of nanoparticles embedded in materials to cause wavelength-shifting effects analogous to fluorescing, other similar or analogous technologies, or any combination thereof for example.

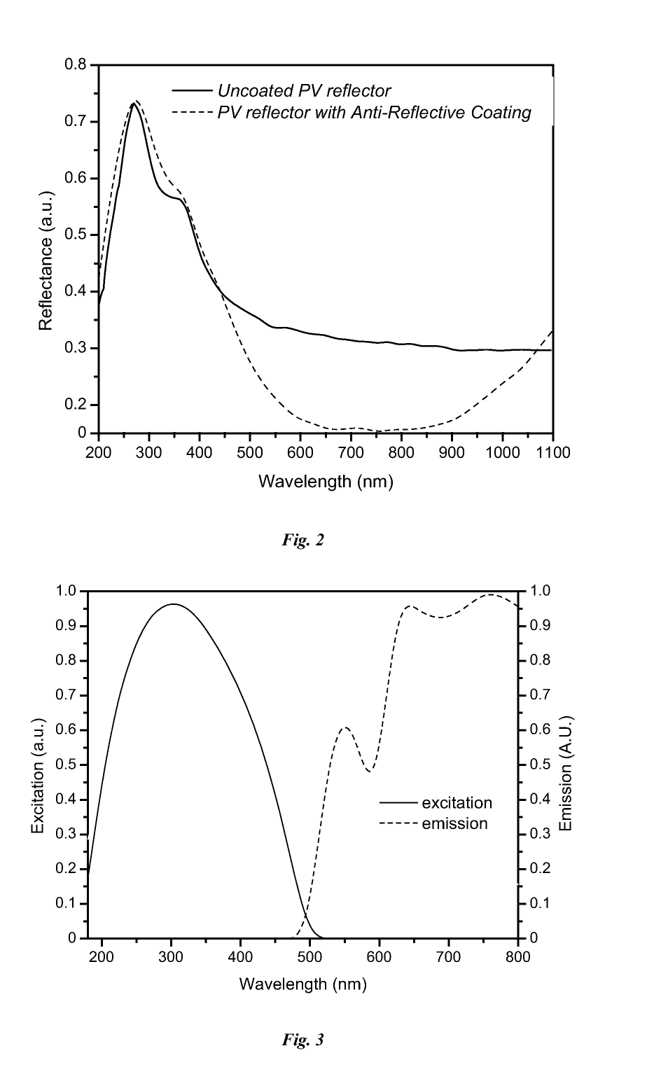

FIG. 2 is a representative graph of optical reflectance properties of the primary photovoltaic receiver without coating and with V-type antireflective coating, showing its increased reflectance at the blue spectral range between 200-450 nm. This blue spectral range corresponds to higher energy bandgaps of the incoming solar radiation 112 relative to the spectral range of wavelengths equal to or longer than 450 nm. Note that the reflectance curves of FIG. 1 relates to the spectral composition of the reflected radiation stream 112′, which preferably consists of predominantly high energy photons due to the interaction of the incoming solar radiation 112 with the primary photovoltaic receiver 114.

FIG. 3 is a sample of excitation and emission graphs for fluorescent material 116. In the preferred embodiment, the reflected radiation stream 112′ spectrally matches the shortwave excitation zone of the fluorescent material 116 indicated in FIG. 3 by the excitation curve shown by solid line. When the reflected radiation stream 112′ is received by the fluorescent material 116 and interacts with it, the fluorescent material 116 generates the fluorescence signal 112″, which has a longer wavelength composition relative to the wavelength composition of the reflected radiation stream 112′. In the preferred embodiment, the wavelength composition of the fluorescence signal 112″ predominantly corresponds to the dashed emission curve of FIG. 3. As indicated in FIG. 3, the fluorescent material 116 may be any device, component, material, fluorescing member or sub-system operable to produce output radiation having a wavelength composition corresponding to the dashed emission curve in response to receiving input radiation having a wavelength composition corresponding to the solid excitation curve, and is not limited to doing so by the phenomenon of optical fluorescence itself.

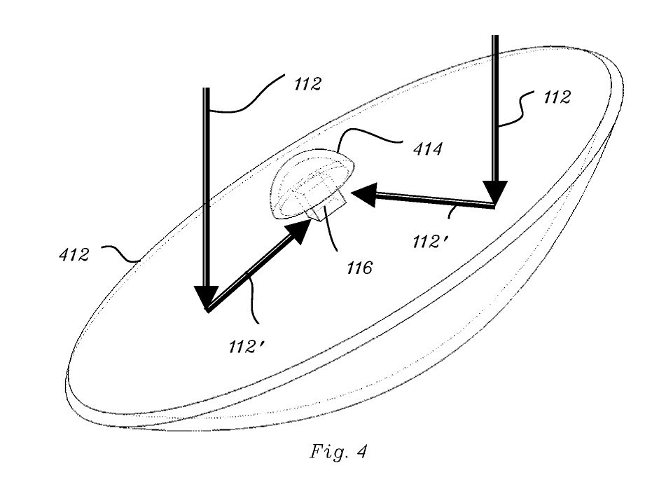

FIG. 4 is a perspective view of a variation of the inherent spectrum-splitting photovoltaic concentrator having radial symmetry. In some embodiments of this variation, the parabolic photovoltaic receiver 412 serves as a primary mirror having a concave front surface facing the fluorescent material target 116. In some embodiments, fluorescence in the fluorescent material target 116 is stimulated in response to the fluorescent material 116 receiving the reflected radiation stream 112′. While FIG. 4 shows the fluorescent material target 116 having a substantially cubic shape, the fluorescent material target 116 may have any suitable shape including spherical, hemispherical, cylindrical, rectangular, planar, curved, etc., and any combination thereof. Fluorescing radiation is typically isotropically emitted from the fluorescent material target 116 and collected by the semi-hemispherical or hemispherical secondary photovoltaic receiver 414, which may be mechanically bonded to the fluorescent material target 116. As indicated by FIG. 4, the secondary photovoltaic receiver 414 need not be mechanically bonded to the fluorescent material target 116, but may disposed within the system in any manner suitable for positioning the secondary photovoltaic receiver 414 for receiving at least a portion of the fluorescing radiation emitted from the fluorescent material target 116 while maintaining clear a path for the reflected radiation stream 112′ to travel from the parabolic photovoltaic receiver 412 to the fluorescent material target 116. The secondary photovoltaic receiver 414 may be disposed in proximity to the fluorescent material target 116, as illustrated in FIG. 4, such as by being supported by either or both of the parabolic photovoltaic receiver 412 and the fluorescent material target 116; may be adhered to either or both of the fluorescent material target 116 and the parabolic photovoltaic receiver 412; may be fastened to either or both of the fluorescent material target 116 and the parabolic photovoltaic receiver 412; may be supported by, adhered to or fastened to a cover window or other structural component of the system; may be disposed by similar or analogous techniques; and may be disposed by any combination thereof for example.

Both receivers 412 and 414 can be constructed by plastic deformation of a semiconductor substrate and aligned with respect to each other for maximum collection efficiency. It is preferred to maintain the optical axis of the concentrator system directed towards the sun, such as by using a two-axis tracking mechanism.

In another embodiment of this invention shown in FIG. 5, the fluorescent material 116 possesses properties of an optical waveguide, such as may result from appropriate selection of the internal material type of the fluorescent material 116 and from a mismatch in index of refraction at the boundary between the body of the fluorescent material 116 and the space between the fluorescent material 116 and the primary photovoltaic receiver 512. As shown in FIG. 5, the primary photovoltaic receiver 512 is arcuately concave at its front surface facing the fluorescent material 116 so as to form the appearance of a trough, which may be a longitudinal trough, parabolic trough or other trough. Also as shown in FIG. 5, the fluorescent material 116 is longitudinal in shape and is optically coupled to tertiary photovoltaic receivers 514 attached to or otherwise in proximity to opposing distal ends of this longitudinal waveguide constituted by the fluorescent material 116. The fluorescent material 116 may have any suitable cross-sectional shape. Reflected solar radiation 112′ which impinges on the waveguide constituted by the fluorescent material 116 will be absorbed into the fluorescent material 116 and then re-emitted isotropically as longer-wavelength radiation. This longer-wavelength radiation reaches the interface of the waveguide with air and it either undergoes multiple acts of total internal reflection and reaches tertiary photovoltaic receiver 514 or leaves the medium of the fluorescent material 116 elsewhere. The secondary photovoltaic receiver 118 is located adjacent the fluorescent material 116 along a side of the fluorescent material 116 other than at the terminal ends of the fluorescent material 116 where the tertiary photovoltaic receivers 514 are located. In some embodiments, the secondary photovoltaic receiver 118 is able to absorb and convert to electricity at least most of the reflected radiation stream 112′ composed of high-energy photons that pass through the fluorescent material 116 absent stimulating emissions within the fluorescent material 116.

It should be appreciated that a top or superficial layer of the secondary photovoltaic receiver 118 is optimized in at least some embodiments for high quantum yield when irradiated with these high-energy photons. Exemplary photovoltaic materials of the top or superficial photovoltaic layer of the secondary photovoltaic receiver 118 include AIGaP and GaP high-bandgap material. In some embodiments, the secondary photovoltaic receiver 118 is able to absorb and convert to electricity at least most of the longer-wavelength radiation that leaves the medium of the fluorescent material 116 in a direction toward the secondary photovoltaic receiver 118. In such embodiments, it is not necessary for the top or superficial photovoltaic layer of the secondary photovoltaic receiver 118 to be optimized for high quantum yield when irradiated with high-energy photons. In some embodiments, the secondary photovoltaic receiver 118 is operable to absorb and convert to electricity at least some of the reflected radiation stream 112′ passing through the fluorescent material 116 toward the secondary photovoltaic receiver 118 absent stimulating emissions within the fluorescent material 116 and at least some of the longer-wavelength radiation that leaves the medium of the fluorescent material 116 in a direction toward the secondary photovoltaic receiver 118.

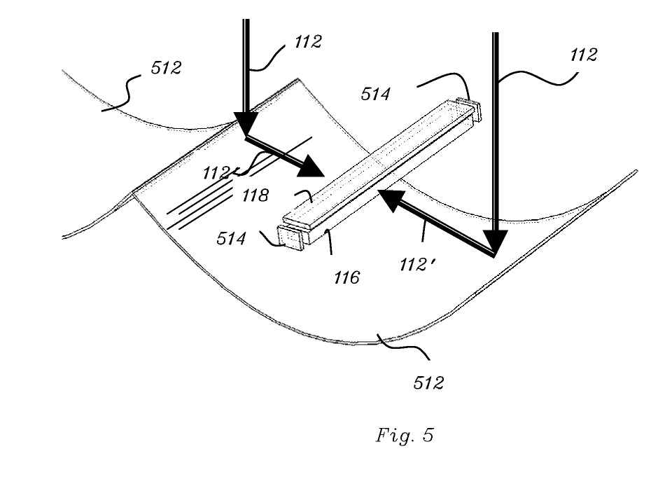

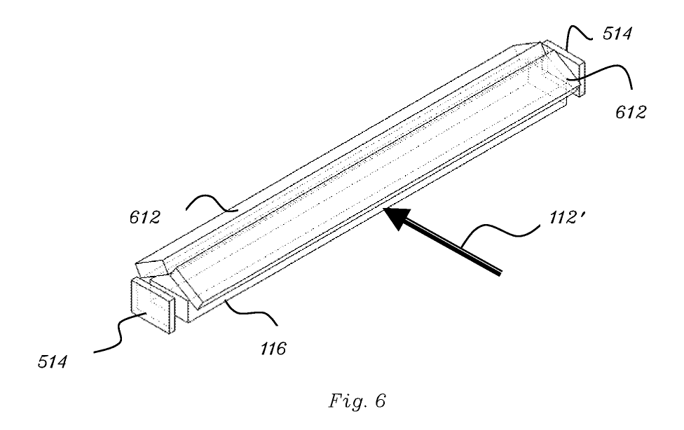

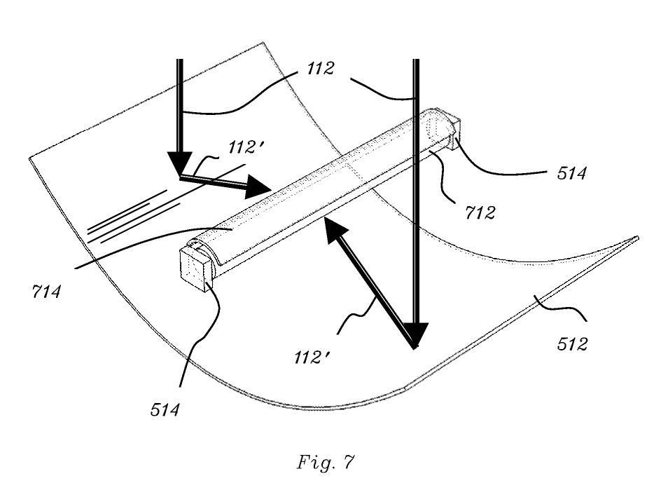

FIG. 6 shows another embodiment of this invention with a pair of flat secondary photovoltaic receivers 612 providing spatial interception of at least a fraction of the output radiation departing from the fluorescent material 116, which may include either or both of the output radiation consisting of longer-wavelength radiation leaving the medium of the fluorescent material 116 and the reflected radiation stream 112′ that scatters inside and passes through the fluorescent material 116 without stimulating emission. As shown in FIG. 6, the secondary photovoltaic receivers 612 are disposed at an angle to each other so as to be advantageously positioned to receive output radiation departing from more than one side of the fluorescent material 116. The embodiment of FIG. 6 advantageously permits capture and conversion to electricity of radiation departing from the fluorescent material 116 within a wider range of departure angles in comparison to the embodiment of FIG. 5.

Another embodiment of the invention may include a single semi-cylindrical secondary photovoltaic receiver 714 as shown in FIG. 7. In this embodiment, the cylindrical fluorescent waveguide 712 is optically coupled at both its ends to a pair of tertiary photovoltaic receivers 514 and the semi-cylindrical secondary photovoltaic receiver 714 absorbs and converts to electricity high energy photons of a portion of reflected radiation stream 112′ that does not stimulate fluorescence. Additionally or alternatively, the semi-cylindrical secondary photovoltaic receiver 714 absorbs and converts to electricity photons of relative low energy having been emitted from the medium of the fluorescent material 116 in a direction toward the semi-cylindrical secondary photovoltaic receiver 714.

In variations, the semi-cylindrical secondary photovoltaic receiver 714 may be separated from, yet in proximity to, the fluorescent material 116; may be fixed to the fluorescent material 116; may be formed as a thin film, such as polymer film or by embedded silicon, deposited onto and integral with the fluorescent material 116; and any combination thereof for example.

In variations, the tertiary photovoltaic receivers 514 may be separated from, yet in proximity to, one or both opposing waveguide ends of the fluorescent material 116; may be fixed to one or both ends; may be formed as a thin film, such as polymer film or by embedded silicon, deposited onto and integral with one or both ends; and any combination thereof for example.

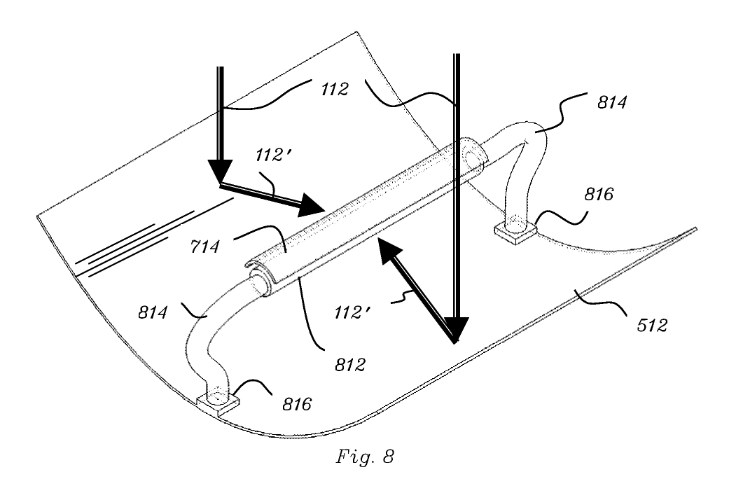

FIG. 8 is a perspective view of another embodiment of the invention and shows the cylindrical fluorescent waveguide 812, which may be formed by fluorescent film on a surface of the optical waveguide 814 for example. As shown in FIG. 8, the optical waveguide 814 is optically coupled at its ends to tertiary photovoltaic receivers 816, which are in some variations of embodiments sensitive to wavelengths of fluorescent emission (FIG. 3). In some variations of embodiments, the tertiary photovoltaic receivers 816 are sensitive to wavelengths of radiation corresponding to the solid excitation curve of FIG. 3. In some variations of embodiments, the tertiary photovoltaic receivers 816 are sensitive to wavelengths of radiation corresponding to both the dashed emission and solid excitation curves of FIG. 3.

Note that the tertiary photovoltaic receivers 816 are shown in FIG. 3 as being attached, including tightly attached, to the primary (trough) photovoltaic receiver 512, which ensures a superior mechanical and thermal bond between the tertiary photovoltaic receivers 816 and the photovoltaic receiver 512. Such bond may be achieved by assembling tertiary photovoltaic cells of the tertiary photovoltaic receivers 816 and fixing such tertiary photovoltaic cells to the photovoltaic cells of the primary photovoltaic receiver 512. Additionally or alternatively, such bond may be achieved by assembling tertiary photovoltaic cells coincident with primary photovoltaic cells on the primary photovoltaic receiver 512, which advantageously provides integral thermal and electrical conductivity for the tertiary photovoltaic receivers 816. As shown in FIG. 8, the tertiary photovoltaic receivers 816 are disposed at the front surface of the photovoltaic receiver 512.

In variations of embodiments, the tertiary photovoltaic receivers 514 (FIGS. 5 to 7) may comprise photovoltaic cells having higher optical-to-electrical energy conversion efficiencies, such as may be found with dual junction photovoltaic cells for example, in comparison to photovoltaic cells of the primary photovoltaic receiver 512 (FIGS. 5 to 8), thereby advantageously providing increased energy conversion efficiency at points of concentrated energy conversion.

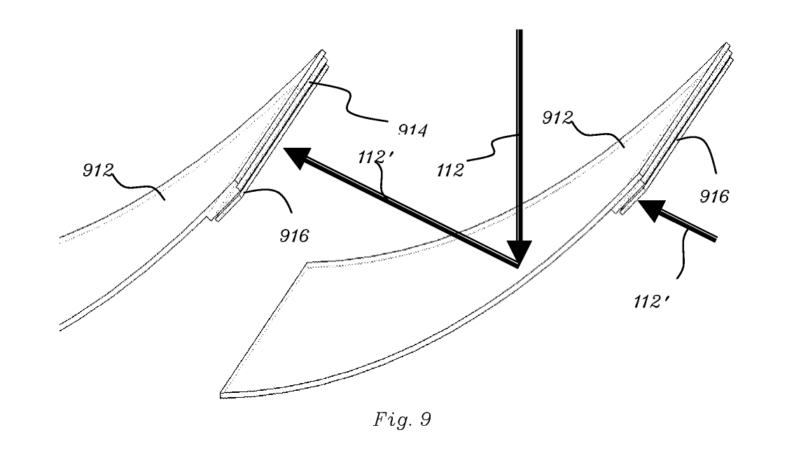

Another embodiment of the invention is shown in FIG. 9 where a secondary photovoltaic receiver 914 is attached to the illustrated back surface of the primary photovoltaic trough receiver 912, such as by using bonding cement. Additionally or alternatively, the secondary photovoltaic receiver 914 can be attached to the primary photovoltaic receiver 912 by any suitable manner, including fastening by fasteners and integrally manufacturing for example. The fluorescent material target 916 is attached to the secondary photovoltaic receiver 914 by an identical, similar, analogous or different technique for attaching the secondary photovoltaic receiver 914 to the back surface of the primary photovoltaic receiver 912.

It should be appreciated that this embodiment is based on the arrangement of photovoltaic receivers 912 in multi-stack arrays such that a given secondary photovoltaic receiver 914 associated with a given primary photovoltaic receiver 912 is attached to the back surface of the particular primary photovoltaic receiver 912 adjacent to the given photovoltaic receiver 912, as illustrated in FIG. 9. In some embodiments, the sensitivity of the secondary photovoltaic receiver 914 is maximized for the spectral content of reflected radiation stream 112′. Additionally or alternatively, the sensitivity of the secondary photovoltaic receiver 914 is in the preferred embodiment optimized for the spectral content of the radiation departing from the fluorescent material target 916 toward the secondary photovoltaic receiver 914.

Note that mutual optical alignment of individual primary photovoltaic trough receivers 912 may be achieved by adding mechanical cross-members or by means of joining one or more of the primary photovoltaic trough receivers 912 to one or more cover windows, such as may be achieved by joining such cover windows to the top or back surface of the concentrator module (i.e. primary photovoltaic trough receiver 912 having a secondary photovoltaic receiver 914 and a fluorescent material target 916 attached thereto).

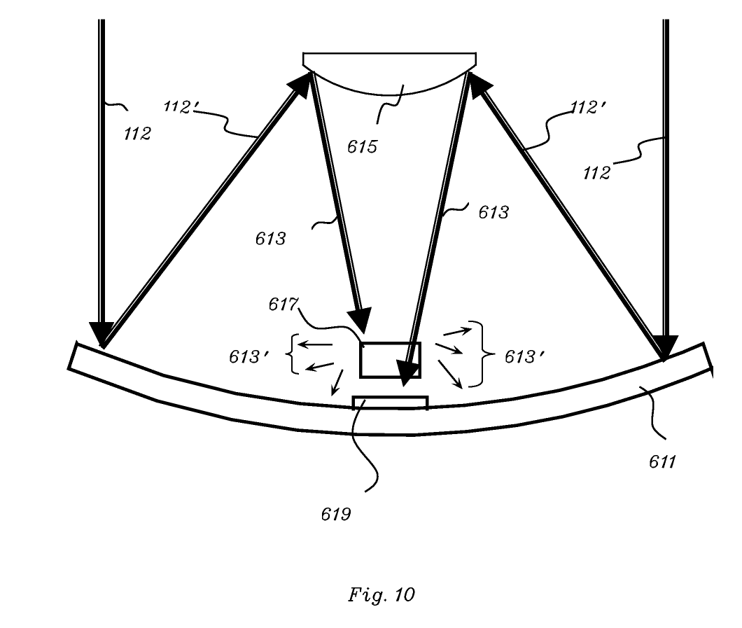

FIG. 10 shows an exemplary diagram of a further embodiment that includes the primary photovoltaic receiver 611 that reflects the incoming solar radiation stream 112 toward the complementary secondary reflector 615, thereby concentrating radiation on the optional fluorescent material 617, on the secondary photovoltaic receiver 619, or on both the optional fluorescent material 617 and the secondary photovoltaic receiver 619. In some embodiments, the secondary photovoltaic receiver 619 is optimized to absorb high energy photons, such as those corresponding to the solid excitation curve of FIG. 3. Additionally or alternatively, the secondary photovoltaic receiver 619 can be optimized to absorb photons of relatively low energy, such as those corresponding to the dashed excitation curve of FIG. 3. In some embodiments, the secondary photovoltaic receiver 619 is integrated into the front surface of the primary photovoltaic receiver 611, thereby advantageously enhancing electrical, thermal and mechanical performance by having the electrical output of the overall system being produced within a single location.

In accordance with the embodiment of FIG. 10, the fluorescent radiation stream 613′, which is produced within the fluorescent material 617 by the stimulation of at least a portion of the radiation reflected at the secondary mirror 615, may be received and converted to electricity by the primary photovoltaic receiver 611, by the secondary photovoltaic receiver 619, or by both the primary photovoltaic receiver 611 and the secondary photovoltaic receiver 619, the selection of which may depend on the angle at which the fluorescent radiation stream 613′ departs from the fluorescent material 617, thereby advantageously permitting the primary photovoltaic receiver 611 to have a smaller radius of curvature than would otherwise be required to achieve a comparably high optical absorption of incoming solar radiation.

As can be seen in FIG. 10, the secondary mirror 615 advantageously reduces the distance between the primary photovoltaic receiver 611 and the furthest extent of the system from the primary photovoltaic receiver 611 by folding the reflected radiation stream 112′, thereby resulting in a more compact system relative to other systems and other embodiments of the present invention.

The system of FIG. 10, in comparison to the use of the primary photovoltaic receiver 611 only, is advantageously operable to capture and convert energy associated with the reflected radiation stream 112′ that would otherwise be lost to the system.

### OPERATION

With reference to the system of FIG. 1 in operation, one places the inherent spectrum-splitting concentrator system of the present invention under diffuse and/or direct incoming solar irradiation stream 112. The user can, when desired, increase the efficiency of the concentrator system in a repeatable manner with the assistance of a sun tracking mechanism. When the optical axis of the concentrator system is pointed towards the sun, at least the following six advantageous and useful effects of the concentrator system are noted:
(1) The primary photovoltaic receiver 114 absorbs and converts into electricity those photons of the incoming radiation stream 112 having energies lower than the predetermined cell bandgap and reflects the radiation stream 112′, which is typically composed of photons having energies greater than the energies of those absorbed by the primary photovoltaic receiver 114.
(2) The primary photovoltaic receiver 114 advantageously increases the power density of the reflected radiation stream 112′ received at the fluorescent material target 116 by focusing the reflected radiation stream 112′ at the fluorescent material target 116, which is optically coupled to the secondary photovoltaic receivers 118.
(3) Since the fluorescent material target 116 absorbs high-energy photons and emits long-wave fluorescing radiation stream 112″ composed of low-energy photons, the long-wave radiation stream 112′ is readily absorbed by the secondary photovoltaic receivers 118, which are optically coupled to the fluorescent material target 116.
(4) The surface of the secondary photovoltaic receiver 118 can be curved inwardly (to result in the hemispherical secondary photovoltaic receiver 414 of FIG. 4 or the semi-cylindrical secondary photovoltaic receiver 714 of FIG. 7 or 8, for example) to capture scattered and fluorescing radiation stream 112″ while advantageously reducing the sun shadow produced by the secondary photovoltaic receiver 118 (or its variations) onto the primary photovoltaic receiver 114.
(5) The concentrator system can be advantageously made more compact by the insertion of the secondary reflector 615 (FIG. 10) in the optical path between primary photovoltaic receiver 611 and the secondary photovoltaic receiver 619 and/or the fluorescent material 617.
(6) Joining the secondary photovoltaic receiver 619 (FIG. 10) to the front surface of the primary photovoltaic receiver 611 (FIG. 10); joining the tertiary photovoltaic receiver 816 (FIG. 8) to the front surface of the primary photovoltaic receiver 512 (FIG. 8); and/or joining the secondary photovoltaic receiver 914 (FIG. 9) to the back surface of the primary photovoltaic receiver 912 (FIG. 9) advantageously increases the thermal mass available for the secondary photovoltaic receiver 619, tertiary photovoltaic receiver 816 and/or secondary photovoltaic receiver 914, respectively, thereby advantageously improving heat dissipation from the secondary photovoltaic receiver 619, tertiary photovoltaic receiver 816 and/or secondary photovoltaic receiver 914.

Thus, since the inherent spectrum-splitting photovoltaic concentrator system described and illustrated in accordance with the above embodiments provides uninterrupted operation under diffuse irradiation and maintains a high-concentration ratio under direct solar irradiation, it avoids both the disadvantage of low efficiency experienced by conventional flat silicon or thin film panels and the limitations of sporadic electricity production under overcast conditions by conventional high-ratio concentrators.

### FURTHER EMBODIMENTS AND VARIATIONS

When the user wishes to simultaneously produce thermal energy and electrical energy, it is only necessary to substitute the secondary photovoltaic receiver 118 (FIG. 1) with a thermal absorber disposed near the focal point of the primary photovoltaic receiver 114.

The active photovoltaic elements of the primary photovoltaic receiver 114 of FIG. 1, the primary photovoltaic receiver 412 of FIG. 4, the primary photovoltaic receiver 512 of FIGS. 5, 7 and 8, the primary photovoltaic receiver 912 of FIG. 9, and the primary photovoltaic receiver 611 of FIG. 10 may be formed to result in monolithic primary photovoltaic receivers in which the photovoltaic elements are integral to the substrates of the primary photovoltaic receivers, respectively; may be formed as discrete elements, including possibly discrete planar elements, attached to a substrate, such as an aluminum-based substrate, to form the overall shapes of the primary photovoltaic receivers 114, 412, 512, 912 and 611; or any combination thereof, for example.

While FIGS. 5 to 7 each show a pair of tertiary photovoltaic receivers 514 disposed at opposing ends of the fluorescent material 116, in a variation one of the pair of tertiary photovoltaic receivers 514 may be substituted with a reflecting mirror to reflect radiation back into the fluorescent material 116 for conversion into electricity at the opposing end of the fluorescent material 116 waveguide. A similar variation may be effected at one end of the optical waveguide 814 of FIG. 8.

Thus, there is provided a photovoltaic energy converting system, the system including: (a) a first photovoltaic converter operable to receive incident solar radiation and convert to electricity those photons of the incident solar radiation having energies less than a predetermined bandgap energy; (b) a fluorescing member positioned for receiving reflected photons having reflected from the first photovoltaic converter, the fluorescing member being operable to produce, in response to the reflected photons, wavelength-shifted photons having energies less than the predetermined bandgap energy; and (c) a second photovoltaic converter operable to convert into electricity the wavelength-shifted photons. The system is thereby advantageously suitable for operation under either direct or diffuse solar irradiation.

The invention has been described and illustrated with particular reference to the above-mentioned embodiments thereof, but it will be understood that reasonable variations and modifications to inherent spectrum-splitting photovoltaic concentrator systems are possible without departing from the spirit and scope of the invention. For example, the substrate of the primary photovoltaic receiver 114 (FIG. 1) could be germanium. Additionally or alternatively, the substrate may be polymer sheet, metal sheet or thin slumped glass, such as may be particularly suitable in the case of manufacturing by thin photovoltaic film deposition at the primary photovoltaic receiver 114. Thus, the embodiments described and illustrated herein should not be considered to limit the invention as construed in accordance with the accompanying claims.

What is claimed is:

1. A photovoltaic energy converting system, the system comprising:
(a) a first photovoltaic converter operable to receive incident solar radiation and convert to electricity those photons of said incident solar radiation having energies less than a predetermined bandgap energy;
(b) a fluorescing member positioned for receiving reflected photons having reflected from said first photovoltaic converter, said fluorescing member being operable to produce, in response to said reflected photons, wavelength-shifted photons having energies less than said predetermined bandgap energy; and
(c) a second photovoltaic converter operable to convert into electricity said wavelength-shifted photons.

2. The system of claim 1 wherein said first photovoltaic converter has a front surface and a back surface opposite said front surface, said incident solar radiation being received by said first photovoltaic converter through said front surface, said reflected photons being predominantly reflected at said front surface.

3. The system of claim 1 wherein said reflected photons predominantly have energies greater than said predetermined bandgap energy.

4. The system of claim 1 wherein said first photovoltaic converter is dimensioned to define a focal point and to concentrate said reflected photons toward said focal point, said first photovoltaic converter having a front surface and a back surface opposite said front surface, said incident solar radiation being received by said first photovoltaic converter through said front surface.

5. The system of claim 4 wherein said first photovoltaic converter at said front surface is substantially parabolically concave.

6. The system of claim 5 wherein said second photovoltaic converter has a receiving surface through which said wavelength-shifted photons are received, said second photovoltaic converter at said receiving surface being substantially hemispherically concave.

7. The system of claim 4 wherein said first photovoltaic converter at said front surface is substantially arcuately concave.

8. The system of claim 7 further comprising an additional said first photovoltaic converter disposed adjacently apart from said first photovoltaic converter, said second photovoltaic converter being attached to said additional photovoltaic converter at a back side thereof, said fluorescing member being disposed substantially between said first photovoltaic converter and said second photovoltaic converter.

9. The system of claim 1 wherein said fluorescing member is dimensioned to have a terminal end, said fluorescing member being operable to guide said wavelength-shifted photons toward said terminal end.

10. The system of claim 9 wherein said second photovoltaic converter is optically coupled to said fluorescing member at said terminal end.

11. The system of claim 10 wherein said first photovoltaic converter has a front surface, said incident solar radiation being received by said first photovoltaic converter through said front surface, and wherein said second photovoltaic converter is attached to said first photovoltaic converter at said front surface.

12. The system of claim 11 wherein said second photovoltaic converter is in thermal contact with said first photovoltaic converter.

13. The system of claim 10 wherein said first photovoltaic converter comprises said second photovoltaic converter.

14. The system of claim 7 wherein said fluorescing member is dimensioned to have a terminal end and one or more sides separate from said terminal end, said fluorescing member being operable to guide a first subset of said wavelength-shifted photons toward said terminal end and to emit a second subset of said wavelength-shifted photons from said fluorescing member at said sides, and further comprising a third photovoltaic converter positioned for receiving said second subset.

15. The system of claim 14 wherein said third photovoltaic converter comprises a pair of substantially planar photovoltaic devices disposed at an angle to each other.

16. The system of claim 14 wherein said third photovoltaic converter is dimensioned to have a semi-cylindrical receiving surface through which said second subset is received.

17. The system of claim 1 further comprising a reflector operable to reflect said reflected photons toward said first photovoltaic converter, said fluorescing member being disposed between said reflector and said first photovoltaic converter.

18. The system of claim 17 wherein said second photovoltaic converter is disposed between said fluorescing member and said first photovoltaic converter.

19. The system of claim 17 wherein said first photovoltaic converter comprises said second photovoltaic converter.

20. An energy converting system, the system comprising:
(a) first means for receiving incident solar radiation, converting to electricity those photons of said incident solar radiation having energies less than a predetermined bandgap energy, and reflecting reflected photons having energies greater than said predetermined bandgap;
(b) second means for producing, in response to said reflected photons, wavelength-shifted photons having energies less than said predetermined bandgap energy; and
(c) third means for converting into electricity said wavelength-shifted photons.
